(19) United States
(12) Patent Application Publication
(10) Pub. No.: US 2006/0205183 A1
(43) Pub. Date: Sep. 14, 2006

(54) Wafer laser processing method and laser beam processing machine

(75) Inventor: Hiroshi Morikazu, Tokyo (JP)

Correspondence Address: SMITH, GAMBRELL & RUSSELL, 1850 M STREET, N.W., SUITE 800, WASHINGTON, DC, 20036, US

(73) Assignee: Disco Corporation

(21) Appl. No.: 11/370,841

(22) Filed: Mar. 9, 2006

(30) Foreign Application Priority Data
Mar. 11, 2005 (JP) 2005-068493

(51) Int. Cl. H01L 21/00; B23K 26/00

(52) U.S. Cl. 438/463; 219/121.82

(57) ABSTRACT

A wafer laser processing method for forming grooves along dividing lines on a wafer, which has a plurality of areas that are sectioned by the dividing lines formed in a lattice pattern on the front surface of a substrate and in which a device is formed in the above respective sectioned areas, comprising the step of applying a laser beam from an incoherent light source to the back surface of the wafer along the dividing lines to form grooves on the back surface of the wafer along the dividing lines.

### FIELD OF THE INVENTION

The present invention relates to a wafer laser processing method for forming a groove along a predetermined dividing line on a wafer such as an optical device wafer, and to a laser beam processing machine.

### DESCRIPTION OF THE PRIOR ART

An optical device wafer comprising optical devices, which are composed of a gallium nitride-based compound semiconductor layer or the like that is laminated in each of a plurality of areas sectioned by dividing lines formed in a lattice pattern on the front surface of a sapphire substrate and the like is divided along the dividing lines into individual optical devices such as light emitting diodes or laser diodes which are widely used in electric appliances.

Cutting along the dividing lines of a wafer such as the above optical device wafer is generally carried out by using a cutting machine for cutting it by rotating a cutting blade at a high speed. However, as the sapphire substrate has such a high Moh's hardness that it is difficult to be cut, the processing speed must be slowed down, thereby reducing productivity.

Meanwhile, as a means of dividing a plate-like workpiece such as a wafer, JP-A 10-305420 discloses a method comprising applying a pulse laser beam along dividing lines formed on a workpiece to form grooves and dividing to cut the workpiece along the laser-processed grooves by a mechanical breaking apparatus.

JP-A 2004-9139 discloses a method comprising applying a pulse laser beam having absorptivity for a sapphire substrate to the substrate to form grooves.

The above laser beam to be applied to form grooves is applied from a YVO4 laser or a YAG laser as a coherent light source. The laser beam of this coherent light source goes straight even when it is hit against a substance which absorbs the laser beam. Therefore, even when a laser beam having absorptivity for a substrate constituting the wafer is applied to the substrate, all the energy of the laser beam is not absorbed by the substrate and the unabsorbed laser beam is discharged to the side opposite to the input side of the workpiece. When a groove is to be formed on an optical device wafer having a plurality of optical devices on the front surface of a sapphire substrate or the like, a laser beam is applied from the back surface side of the wafer so as to prevent damage caused by the adhesion of debris produced at the time of laser processing to an optical device formed on the front surface of the substrate. However, when the laser beam not absorbed by the substrate reaches the front surface of the substrate, a problem arises that it damages a device layer formed on the front surface of the substrate, thereby reducing the quality of an optical device.

### SUMMARY OF THE INVENTION

It is an object of the present invention to provide a wafer laser processing method, which can form a groove along dividing lines on the back surface of a wafer without damaging the front surface of the wafer by applying a laser beam to the back surface of the wafer along a predetermined dividing line; and a laser beam processing machine used therefor.

To attain the above object, according to the present invention, there is provided a wafer laser processing method for forming grooves along dividing lines on a wafer, which has a plurality of areas that are sectioned by the dividing lines formed in a lattice pattern on the front surface of a substrate and in which a device is formed in the above respective sectioned areas, comprising the step of:

applying a laser beam from an incoherent light source from the back surface side of the wafer along the dividing lines to form grooves on the back surface of the wafer along the dividing lines.

The above substrate is a sapphire substrate, and the wavelength of the above laser beam is set to 200 nm or less.

Further, according to the present invention, there is provided a laser beam processing machine comprising a chuck table for holding a workpiece and a laser beam application means for applying a laser beam to the workpiece held on the chuck table, wherein

the laser beam application means comprises an incoherent light source as a light source for the laser beam.

According to the present invention, since the laser beam of the incoherent light source is applied from the back surface side of the wafer along the dividing lines, the energy of the laser beam is absorbed at a position near the back surface of the wafer, to which the laser beam is applied, and the laser beam does not reach the front surface of the wafer. Accordingly, the devices formed on the front surface of the substrate are not damaged by the energy of the laser beam.

### BRIEF DESCRIPTION OF THE DRAWINGS

FIG. 1 is a perspective view of a laser beam processing machine constituted according to the present invention;

FIG. 2 is a block diagram schematically showing the constitution of laser beam application means provided in the laser beam processing machine shown in FIG. 1;

FIG. 3 is a perspective view of an optical device wafer as a wafer to be processed by the present invention;

FIG. 4 is an enlarged sectional view of the principal portion of the optical device wafer shown in FIG. 3;

FIG. 5 is a perspective view showing a state where a protective tape is affixed to the front surface of the optical device wafer shown in FIG. 3;

FIGS. 6(a) and 6(b) are explanatory diagrams showing the laser beam application step in the wafer laser processing method of the present invention;

FIG. 7 is an enlarged sectional view of the principal portion of the optical device wafer processed by the laser beam application step shown in FIGS. 6(a) and 6(b); and

FIG. 8 is a graph showing the light transmittance of sapphire.

### DETAILED DESCRIPTION OF THE PREFERRED EMBODIMENTS

Preferred embodiments of the wafer laser processing method and the laser beam processing machine according to the present invention will be described in detail hereinunder with reference to the accompanying drawings.

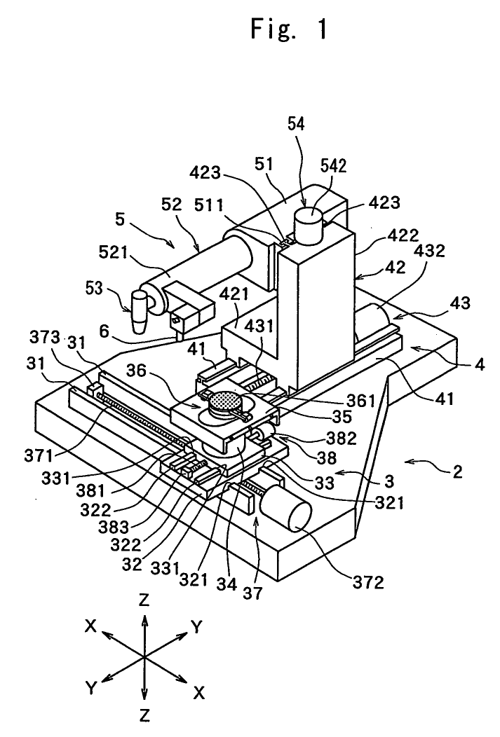

FIG. 1 is a perspective view of a laser beam processing machine constituted according to the present invention. The laser beam processing machine shown in FIG. 1 comprises a stationary base 2, a chuck table mechanism 3 for holding a workpiece, which is mounted on the stationary base 2 in such a manner that it can move in a processing-feed direction indicated by an arrow X, a laser beam application unit support mechanism 4 mounted on the stationary base 2 in such a manner that it can move in an indexing-feed direction indicated by an arrow Y perpendicular to the direction indicated by the arrow X, and a laser beam application unit 5 mounted on the laser beam application unit support mechanism 4 in such a manner that it can move in a focal position adjustment direction indicated by an arrow Z.

The above chuck table mechanism 3 comprises a pair of guide rails 31 and 31, which are mounted on the stationary base 2 and arranged parallel to each other in the direction indicated by the arrow X, a first sliding block 32 mounted on the guide rails 31 and 31 in such a manner that it can move in the direction indicated by the arrow X, a second sliding block 33 mounted on the first sliding block 32 in such a manner that it can move in the direction indicated by the arrow Y, a support table 35 supported on the second sliding block 33 by a cylindrical member 34, and a chuck table 36 as workpiece holding means. This chuck table 36 is made of a porous material and has a workpiece holding surface 361, and a plate-like workpiece, for example, disk-like semiconductor wafer is held on the chuck table 36 by a suction means that is not shown. The chuck table 36 is rotated by a pulse motor (not shown) installed in the cylindrical member 34.

The above first sliding block 32 has, on its undersurface, a pair of to-be-guided grooves 321 and 321 to be fitted to the above pair of guide rails 31 and 31 and, on its top surface, a pair of guide rails 322 and 322 formed parallel to each other in the direction indicated by the arrow Y. The first sliding block 32 constituted as described above can move in the direction indicated by the arrow X along the pair of guide rails 31 and 31 by fitting the to-be-guided grooves 321 and 321 to the pair of guide rails 31 and 31, respectively. The chuck table mechanism 3 in the illustrated embodiment comprises a processing-feed means 37 for moving the first sliding block 32 along the pair of guide rails 31 and 31 in the direction indicated by the arrow X. The processing-feed means 37 comprises a male screw rod 371 arranged between the above pair of guide rails 31 and 31 parallel thereto, and a drive source such as a pulse motor 372 for rotary-driving the male screw rod 371. The male screw rod 371 is, at its one end, rotatably supported to a bearing block 373 fixed on the above stationary base 2 and is, at the other end, transmission-coupled to the output shaft of the above pulse motor 372 via a speed reducer that is not shown. The male screw rod 371 is screwed into a threaded through-hole formed in a female screw block (not shown) projecting from the undersurface of the center portion of the first sliding block 32. Therefore, by driving the male screw rod 371 in a normal direction or reverse direction with the pulse motor 372, the first sliding block 32 is moved along the guide rails 31 and 31 in the processing-feed direction indicated by the arrow X.

The above second sliding block 33 has, on its undersurface, a pair of to-be-guided grooves 331 and 331 to be fitted to the pair of guide rails 322 and 322 on the top surface of the above first sliding block 32 and can move in the direction indicated by the arrow Y by fitting the to-be-guided grooves 331 and 331 to the pair of guide rails 322 and 322, respectively. The chuck table mechanism 3 in the illustrated embodiment comprises a first indexing-feed means 38 for moving the second sliding block 33 in the direction indicated by the arrow Y along the pair of guide rails 322 and 322 on the first sliding block 32. The first indexing-feed means 38 comprises a male screw rod 381, which is arranged between the above pair of guide rails 322 and 322 parallel thereto, and a drive source such as a pulse motor 382 for rotary-driving the male screw rod 381. The male screw rod 381 is, at its one end, rotatably supported to a bearing block 383 fixed on the top surface of the above first sliding block 32 and is, at the other end, transmission-coupled to the output shaft of the above pulse motor 382 through a speed reducer that is not shown. The male screw rod 381 is screwed into a threaded through-hole formed in a female screw block (not shown) projecting from the undersurface of the center portion of the second sliding block 33. Therefore, by driving the male screw rod 381 in a normal direction or reverse direction with the pulse motor 382, the second sliding block 33 is moved along the guide rails 322 and 322 in the indexing-feed direction indicated by the arrow Y.

The above laser beam application unit support mechanism 4 comprises a pair of guide rails 41 and 41 mounted on the stationary base 2 and arranged parallel to each other in the direction indicated by the arrow Y and a movable support base 42 mounted on the guide rails 41 and 41 in such a manner that it can move in the direction indicated by the arrow Y. This movable support base 42 comprises a movable support portion 421 movably mounted on the guide rails 41 and 41 and a mounting portion 422 mounted on the movable support portion 421. The mounting portion 422 is provided with a pair of guide rails 423 and 423 extending parallel to each other in the direction indicated by the arrow Z on one of its flanks. The laser beam application unit support mechanism 4 in the illustrated embodiment comprises a second indexing-feed means 43 for moving the movable support base 42 along the pair of guide rails 41 and 41 in the direction indicated by the arrow Y. This second indexing-feed means 43 comprises a male screw rod 431 that is arranged between the above pair of guide rails 41 and 41 parallel thereto, and a drive source such as a pulse motor 432 for rotary-driving the male screw rod 431. The male screw rod 431 is, at its one end, rotatably supported to a bearing block (not shown) fixed on the above stationary base 2 and is, at the other end, transmission-coupled to the output shaft of the above pulse motor 432 via a speed reducer that is not shown. The male screw rod 431 is screwed into a threaded through-hole formed in a female screw block (not shown) projecting from the undersurface of the center portion of the movable support portion 421 constituting the movable support base 42. Therefore, by driving the male screw rod 431 in a normal direction or reverse direction with the pulse motor 432, the movable support base 42 is moved along the guide rails 41 and 41 in the indexing-feed direction indicated by the arrow Y.

The laser beam application unit 5 in the illustrated embodiment comprises a unit holder 51 and a laser beam application means 52 secured to the unit holder 51. The unit holder 51 has a pair of to-be-guided grooves 511 and 511 to be slidably fitted to the pair of guide rails 423 and 423 on the above mounting portion 422 and is supported in such a manner that it can move in the direction indicated by the arrow Z by fitting the to-be-guided grooves 511 and 511 to the above guide rails 423 and 423, respectively.

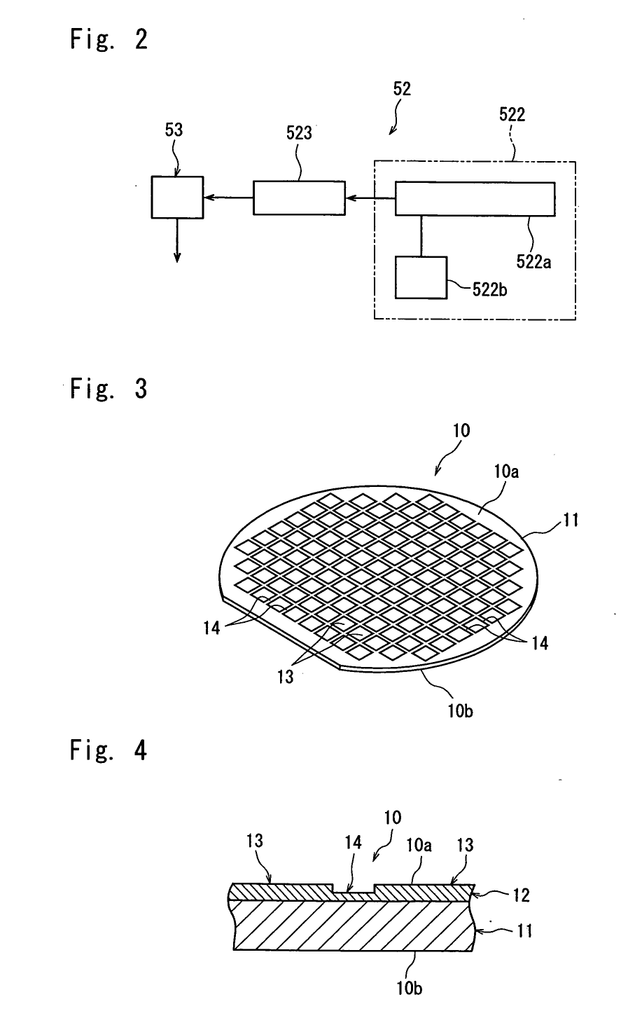

The illustrated laser beam application means 52 comprises a cylindrical casing 521 that is secured to the above unit holder 51 and extends substantially horizontally. In the casing 521, there are installed a pulse laser beam oscillation means 522 and a transmission optical system 523, as shown in FIG. 2. The pulse laser beam oscillation means 522 is constituted by an excimer laser beam oscillator 522a which is an incoherent light source in the illustrated embodiment and a repetition frequency setting means 522b connected to the excimer laser beam oscillator 522a. The above transmission optical system 523 has suitable optical elements such as a beam splitter, etc. A condenser 53 for converging a laser beam, which is oscillated from the above pulse laser beam oscillation means 522 and is transmitted via the transmission optical system 523, is attached to the end of the above casing 521.

Returning to FIG. 1, an image pick-up means 6 for detecting the area to be processed by the above laser beam application means 52 is mounted on the front end of the casing 521 constituting the above laser beam application means 52. This image pick-up means 6 comprises an infrared illuminating means for applying infrared radiation to the workpiece, an optical system for capturing the infrared radiation applied by the infrared illuminating means, and an image pick-up device (infrared CCD) for outputting an electric signal corresponding to the infrared radiation captured by the optical system, in addition to an ordinary image pick-up device (CCD) for picking up an image with visible radiation in the illustrated embodiment. An image signal is supplied to a control means that is not shown.

The laser beam application unit 5 in the illustrated embodiment comprises a moving means 54 for moving the unit holder 51 along the pair of guide rails 423 and 423 in the direction indicated by the arrow Z. The moving means 54 comprises a male screw rod (not shown) arranged between the pair of guide rails 423 and 423 and a drive source such as a pulse motor 542 for rotary-driving the male screw rod. By driving the male screw rod (not shown) in a normal direction or reverse direction with the pulse motor 542, the unit holder 51 and the laser beam application means 52 are moved along the guide rails 423 and 423 in the direction indicated by the arrow Z. In the illustrated embodiment, the laser beam application means 52 is moved up by driving the pulse motor 542 in a normal direction and moved down by driving the pulse motor 542 in the reverse direction.

The laser beam processing machine in the illustrated embodiment is constituted as described above, and its function will be described hereinbelow.

Here, an optical device wafer as a workpiece to be processed by the above laser beam processing machine will be described with reference to FIG. 3 and FIG. 4. FIG. 3 is a perspective view of the optical device wafer and FIG. 4 is an enlarged sectional view of the principal portion of the optical device wafer shown in FIG. 3.

In the optical device wafer 10 shown in FIG. 3 and FIG. 4, a plurality of devices 13 composed of a device layer 12, in which layers formed from gallium nitride (GaN), aluminum nitride gallium (AlGaN) or the like are laminated, are formed in a matrix on the front surface of a sapphire substrate 11. The devices 13 are sectioned by dividing lines 14 formed in a lattice pattern.

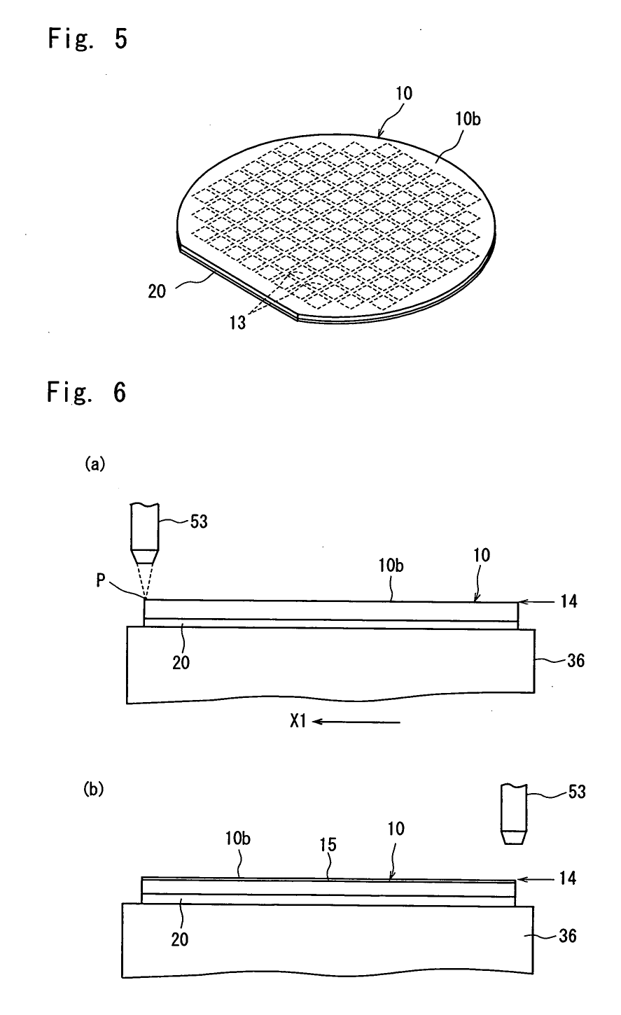

For the laser processing of the back surface 10b of the optical device wafer 10 constituted as described above, a protective tape 20 is affixed to the front surface 10a of the optical device wafer 10, as shown in FIG. 5 (protective tape affixing step).

The above protective tape affixing step is followed by a laser beam application step for forming a groove along the dividing lines 14 on the back surface 10b of the optical device wafer 10. In this laser beam application step, the protective tape 20 side of the optical device wafer 10 is first placed on the chuck table 36 of the laser beam processing machine shown in FIG. 1 and suction-held on the chuck table 36. Therefore, the back surface 10b of the optical device wafer 10 faces up.

The chuck table 36 suction-holding the optical device wafer 10 as described above is brought to a position right below the image pick-up means 6 by the processing-feed means 37. After the chuck table 36 is positioned right below the image pick-up means 6, alignment work for detecting the area to be processed of the optical device wafer 10 is carried out by the image pick-up means 6 and the control means that is not shown. That is, the image pick-up means 6 and the control means (not shown) carry out image processing such as pattern matching etc. to align a dividing line 14 formed in a predetermined direction of the optical device wafer 10 with the condenser 53 of the laser beam application means 52 for applying a laser beam along the dividing line 14, thereby performing the alignment of a laser beam application position. The alignment of the laser beam application position is also carried out on dividing lines 14 formed on the optical device wafer 10 in a direction perpendicular to the above predetermined direction. Although the front surface 10a having the dividing lines 14 formed thereon of the optical device wafer 10 faces down at this point, as the image pick-up means 6 comprises the infrared illuminating means, an optical system for capturing infrared radiation and an image pick-up device (infrared CCD) for outputting an electric signal corresponding to the infrared radiation as described above, images of the dividing lines 14 can be picked up through the back surface 10b.

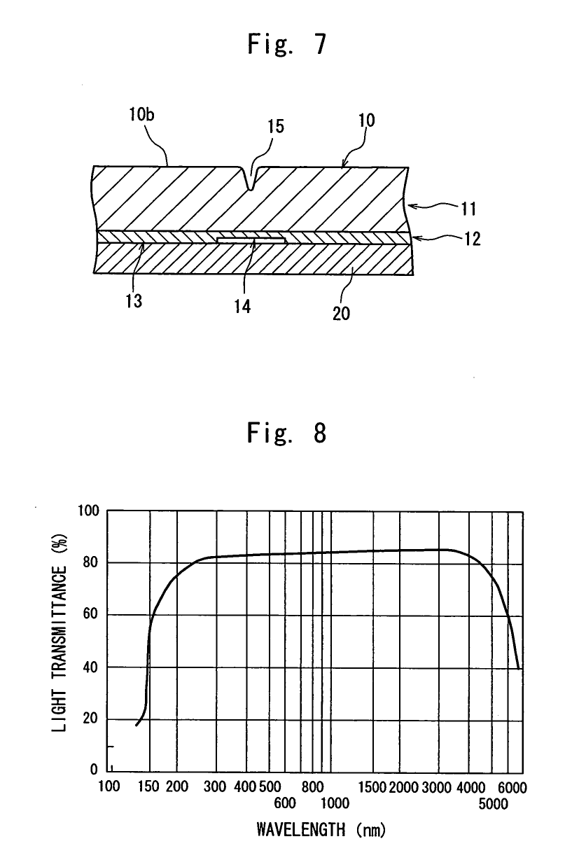

After the alignment of the laser beam application position is carried out by detecting the dividing line 14 formed on the optical device wafer 10 held on the chuck table 36 as described above, the chuck table 36 is moved to a laser beam application area where the condenser 53 of the laser beam application means 52 is located so as to bring the predetermined dividing line 14 to a position right below the condenser 53 as shown in FIG. 6(a). At this point, as shown in FIG. 6(a), the optical device wafer 10 is positioned such that one end (left end in FIG. 6(a)) of the dividing line 14 is located right below the condenser 53. The chuck table 36, that is, the optical device wafer 10 is then moved in the direction indicated by the arrow X1 in FIG. 6(a) at a predetermined feed rate while a laser beam is applied from the condenser 53. When the other end (right end in FIG. 6(b)) of the dividing line 14 reaches a position right below the condenser 53 as shown in FIG. 6(b), the application of the pulse laser beam is suspended, and the movement of the chuck table 36, that is, the optical device wafer 10 is stopped. As a result, a groove 15 is formed along the predetermined dividing line 14 on the back surface 10b of the optical device wafer 10, as shown in FIG. 7.

The processing conditions in the above laser beam application step are set as follows, for example.
Light source: incoherent light source (excimer laser)
Wavelength: 193 nm
Output: 1 to 25 W
Repetition frequency: 1 to 50 kHz
Focusing spot diameter: 10 to 200 μm
Processing-feed rate: 10 to 400 mm/sec.

Under the above processing conditions of the laser beam application step, the pulse laser beam spot is circular. The pulse laser beam spot, however, is desirably elliptic. That is, by making the laser beam spot elliptic, the ratio of pulse laser beam spots overlapping with one another can be increased, thereby making it possible to form a continuous groove 15 without fail.

Here, the wavelength and the light source of the pulse laser beam applied in the above laser beam application step will be discussed hereinbelow.

FIG. 8 is a graph showing the light transmittance of sapphire, and the horizontal axis shows a wavelength and the vertical axis shows a light transmittance. As understood from FIG. 8, when the wavelength is 300 nm or more, the light transmittance becomes 83% or more, which means that the percentage of a laser beam which contributes to the actual processing is 17% or less. It is also understood that the wavelength at which sapphire begins to absorb a laser beam is 200 nm or less. Therefore, it is desired that a laser beam having a wavelength of 200 nm or less should be used in order to have the energy of the laser beam contribute to processing effectively.

In the present invention, the incoherent light source is used as a light source for the laser beam. The laser beam from the incoherent light source is scattered and reflected in a moment that it hits against a substance that absorbs the laser beam. Therefore, as the energy of the laser beam is absorbed at a position near the surface to which the laser beam is applied, the laser beam does not reach the surface opposite to the illuminated surface. Accordingly, as described above, the laser beam applied from the back surface 10b side of the optical device wafer 10 does not reach the front surface 10a. Consequently, the device layer 12 formed on the front surface of the substrate 11 is not damaged by the energy of the laser beam.

After the above laser beam application step is carried out along all the dividing lines 14 formed in the predetermined direction of the optical device wafer 10, the chuck table 36, therefore, the optical device wafer 10 is turned at 90°. The above laser beam application step is carried out along all dividing lines 14 formed on the optical device wafer 10 in a direction perpendicular to the above predetermined direction.

After the above laser beam application step is carried out along all the dividing lines 14 formed on the optical device wafer 10 as described above, the optical device wafer 10 is carried to the subsequent dividing step. In the dividing step, as the grooves 15 formed along the dividing lines 14 of the optical device wafer 10 are formed to a depth that the optical device wafer 10 can be easily divided, the optical device wafer 10 can be easily divided by mechanical breaking.

While an example in which the present invention is applied to an optical device wafer has been described above, the same effect and function are obtained even when the present invention is applied to laser processing along the streets of a semiconductor wafer having a plurality of circuits on the front surface of a substrate.

What is claimed is:

1. A wafer laser processing method for forming grooves along dividing lines on a wafer, which has a plurality of areas that are sectioned by the dividing lines formed in a lattice pattern on the front surface of a substrate in which a device is formed in the above respective sectioned areas, comprising the step of:
applying a laser beam from an incoherent light source to the back surface of the wafer along the dividing lines to form grooves on the back surface of the wafer along the dividing lines.

2. The wafer laser processing method according to claim 1, wherein the substrate is a sapphire substrate, and the wavelength of the laser beam is set to 200 nm or less.

3. A laser beam processing machine comprising a chuck table for holding a workpiece and a laser beam application means for applying a laser beam to the workpiece held on the chuck table, wherein
the laser beam application means comprises an incoherent light source as a light source for the laser beam.
